(19) United States
(12) Patent Application Publication
(10) Pub. No.: US 2024/0136989 A1
(43) Pub. Date: Apr. 25, 2024

(54) System for Detecting External Reference Resistor in Voltage Supply Path

(71) Applicant: Texas Instruments Incorporated, Dallas, TX (US)

(72) Inventors: Harsh Sheokand, Hisar (IN); Tarunvir Singh, Bangalore (IN); Anant Kamath, Bangalore (IN); Suvadip Banerjee, Bangalore (IN)

(21) Appl. No.: 17/972,518

(22) Filed: Oct. 23, 2022

(51) Int. Cl. H03F 3/45

(52) U.S. Cl. CPC H03F 3/45654; H03F 3/45183; H03F 2203/45526

(57) ABSTRACT

A system includes an operational amplifier which includes a first amplifier input, a second amplifier input and an amplifier output. The system includes a first switch which includes a first terminal and includes a second terminal coupled to the first amplifier input. The system includes a second switch which includes a first terminal coupled to the first amplifier input and a second terminal coupled to the second amplifier input. The system includes a first bias current source coupled between the first amplifier input and a common potential and includes a second bias current source coupled between the first terminal of the first switch and the common potential. The system includes a feedback path between the amplifier output and the first amplifier input.

### TECHNICAL FIELD

This description relates generally to systems for detecting an external reference resistor in a voltage supply path.

### BACKGROUND

In industrial, automotive, petrochemical, fire control, communications and power systems, sensors are used to detect critical information. The sensors may, for example, be temperature sensors, pressure sensors, or motion sensors. Generally, to operate sensors properly, it is necessary to draw a required amount of current from the sensors or to provide a required amount of current into the sensors.

An external component (such as a resistor, capacitor and/or inductor) may be used with a programmable device that provides current to or draws current from another device. Based on the value of the external component, the programmable device provides a particular amount of current. For example, a user may connect an external reference resistor to an interface or buffer so as to “program” the amount of current sourced to/drawn from a circuit (such as a sensor). The resistance of the external reference resistor may be sensed, and a corresponding current is generated by the interface or buffer circuit. Based on the current, the interface or buffer circuit may draw from the sensors or supply current to the sensors.

Some existing solutions for sensing the resistance of an external reference resistor require a dedicated pin or a terminal of an integrated circuit (IC) for a connection to the external reference resistor. A known voltage or a known current is applied to the external reference resistor and its resistance is sensed.

It is desirable to reduce the number of pins or terminals of ICs required to sense the external reference resistor, and thus decrease the size of IC packages.

### SUMMARY

In one aspect, a system includes a system input and a system output. The system includes an operational amplifier which includes a first amplifier input coupled to the system input and includes a second amplifier input and an amplifier output. The system includes a first switch which includes a first terminal and includes a second terminal coupled to the first amplifier input. The system includes a second switch which includes a first terminal coupled to the first amplifier input and a second terminal coupled to the second amplifier input. The system includes a first bias current source coupled between the first amplifier input and a common potential and includes a second bias current source coupled between the first terminal of the first switch and the common potential. The system includes a third switch which includes a first terminal coupled to the amplifier output and includes a second terminal. The system includes a first transistor which includes a first current terminal, a second current terminal coupled to the common potential and a control terminal coupled to the second terminal of the third switch. The system includes a fourth switch which includes a first terminal coupled to the system input and a second terminal coupled to the first current terminal of the first transistor.

In an additional aspect, the system includes a first capacitor coupled between the second amplifier input and the common potential and a second capacitor coupled between the control terminal of the first transistor and the common potential.

In an additional aspect, the system includes a second transistor which includes a first current terminal coupled to the system output, a second current terminal coupled to the common potential and a control terminal coupled to the second terminal of the third switch.

In an additional aspect, the system includes a first resistor coupled between the system input and the first amplifier input.

In an additional aspect, an external resistor detection circuit includes an operational amplifier which includes a first amplifier input adapted to be coupled to the external resistor and includes a second amplifier input and an amplifier output. The circuit includes a first switch which includes a first terminal and includes a second terminal coupled to the first amplifier input. The circuit includes a second switch which includes a first terminal coupled to the first amplifier input and a second terminal coupled to the second amplifier input. The circuit includes a first bias current source coupled between the first amplifier input and a common potential and a second bias current source coupled between the first terminal of the first switch and the common potential. The circuit includes a third switch which includes a first terminal coupled to the amplifier output and includes a second terminal. The circuit includes a first transistor which includes a first current terminal, a second current terminal coupled to the common potential, and a control terminal coupled to the second terminal of the third switch. The circuit includes a fourth switch which includes a first terminal coupled to the system input and a second terminal coupled to the first terminal of the first transistor. The circuit includes a first capacitor coupled between the second amplifier input and the common potential and a second capacitor coupled between the control terminal of the first transistor and the common potential.

In an additional aspect, a circuit includes an external terminal adapted to be coupled to an external resistor. The circuit includes an operational amplifier which includes a first amplifier input coupled to the external terminal and includes a second amplifier input and an amplifier output. The circuit includes a first capacitor coupled between the second amplifier input and a common potential. The circuit includes a feedback path which includes a first terminal coupled to the amplifier output and a second terminal coupled to the external terminal. The feedback path is configured to provide an output current corresponding to the resistance of the external resistor.

### BRIEF DESCRIPTION OF THE DRAWINGS

FIG. 1 is a block diagram illustrating a system of an example embodiment.

FIGS. 2A, 2B and 2C are circuit diagrams illustrating a detector circuit of an example embodiment.

FIG. 3 is a timing diagram illustrating voltages generated in the detector circuit of FIGS. 2A-2C.

FIG. 4 is a circuit diagram illustrating a detector which is an example implementation of the detector of FIGS. 2A-2C.

The same reference numerals or other reference designators are used in the drawings to designate the same or similar (functionally and/or structurally) features.

### DETAILED DESCRIPTION

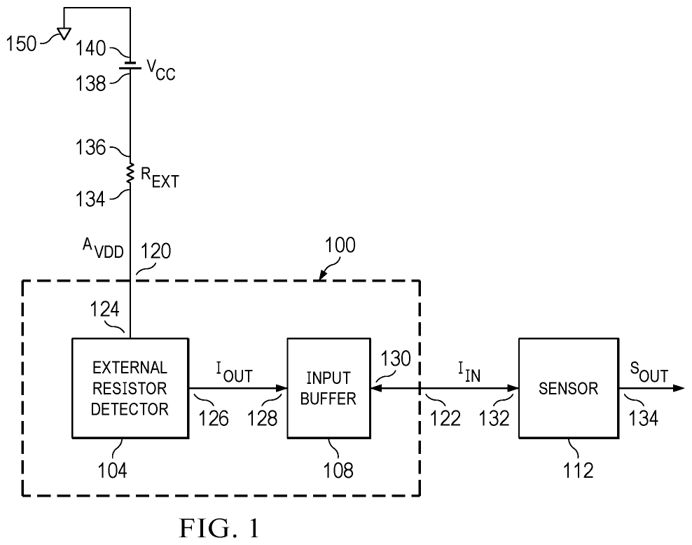

FIG. 1 is a block diagram illustrating system 100 of an example embodiment. System 100 may be used, for example, in industrial systems, automotive systems, petrochemical systems, fire control systems, communication systems and power systems. In some example embodiments, system 100 may be implemented in an integrated circuit (IC) or a semiconductor die.

System 100 includes system input 120 and system input/output 122. In some example embodiments, system input 120 and system input/output 122 may be connected to external terminals of an IC. The external terminals may be pins, leads (e.g., J-leads), balls (such as in a ball-grid array) or leadless terminals. The external terminals allow connections between system 100 and other circuitry or systems.

System 100 includes detector 104 which includes detector input 124 coupled to system input 120 and incudes detector output 126. System 100 includes input buffer 108 which includes buffer input 128 coupled to detector output 126 and includes buffer output 130 coupled to system output 122. In some example embodiments, input buffer 108 may include an analog-to-digital (A/D) converter (not shown in FIG. 1), a buffer amplifier (not shown in FIG. 1), and/or a micro-controller or processor (not shown in FIG. 1).

Input buffer 108 may be coupled to sensor 112. Sensor 112 includes sensor input/output 132 coupled to system input/output 122. Sensor 112 may, for example, be a temperature sensor, a pressure sensor or a motion sensor. Sensor 112 provides output signal Spur at sensor output 134 which may represent a measured quantity such as a temperature, a pressure or a motion. Sensor output 134 may be coupled to processor and/or other analog or digital circuitry (which may be included in system 100 or another system).

System 100 is configured to detect a resistance of an external reference resistor R_{EXT} (e.g., between around 700 ohms to around 4K ohms) in a supply path. Here, the supply path refers to a conduction path between voltage supply V_{CC} (e.g., around 24V) and system input 120. External reference resistor R_{EXT} includes first terminal 134 coupled to system input 120 and includes second terminal 136. Voltage supply V_{CC} includes first terminal 138 coupled to second terminal 136 of R_{EXT} and includes second terminal 140 coupled to common potential 150 (e.g., ground). When system input 120 is coupled to voltage supply V_{CC} via R_{EXT}, voltage A_{VDD} appears at system input 120.

To operate sensor 112 properly, input buffer 108 draws a particular amount of current from sensor 112 or provides a particular amount of current into sensor 112. In some example embodiments, detector 104 determines a resistance of R_{EXT} and based on the resistance value provides output current I_{OUT} (which corresponds to the resistance value of R_{EXT}). Based on the value of I_{OUT}, input buffer 108 draws current I_{IN} from sensor 112 or provides current I_{IN} into sensor 112. A user may, for example, connect R_{EXT} in the supply path between system input 120 and supply voltage V_{CC}, and based on the resistance value of R_{EXT}, detector 104 provides a corresponding I_{OUT} to input buffer 108. In response to the value of I_{OUT}, input buffer 108 current draws I_{IN} from sensor 112 or provides current I_{IN} to sensor 112. As such, system 100 provides a current programmability based on R_{EXT}.

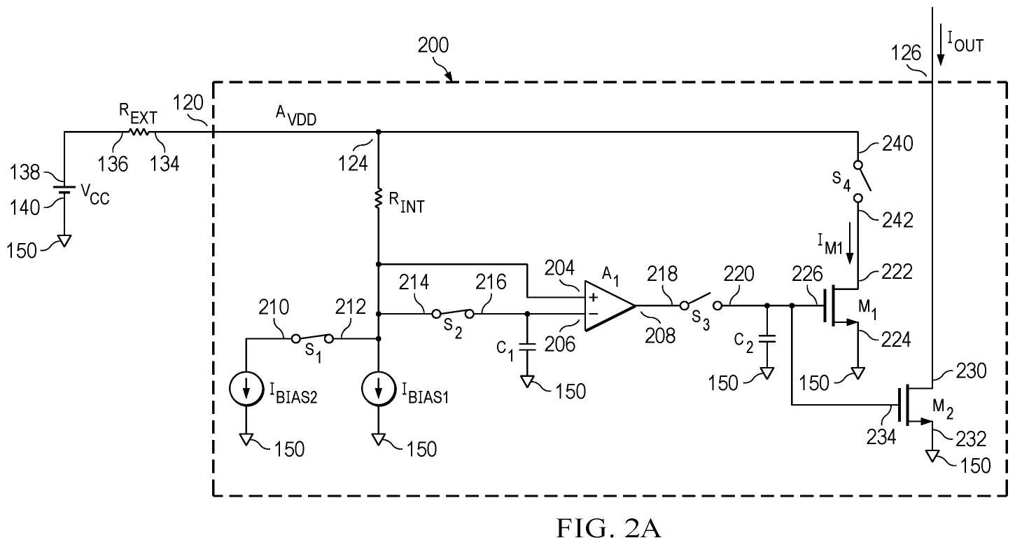

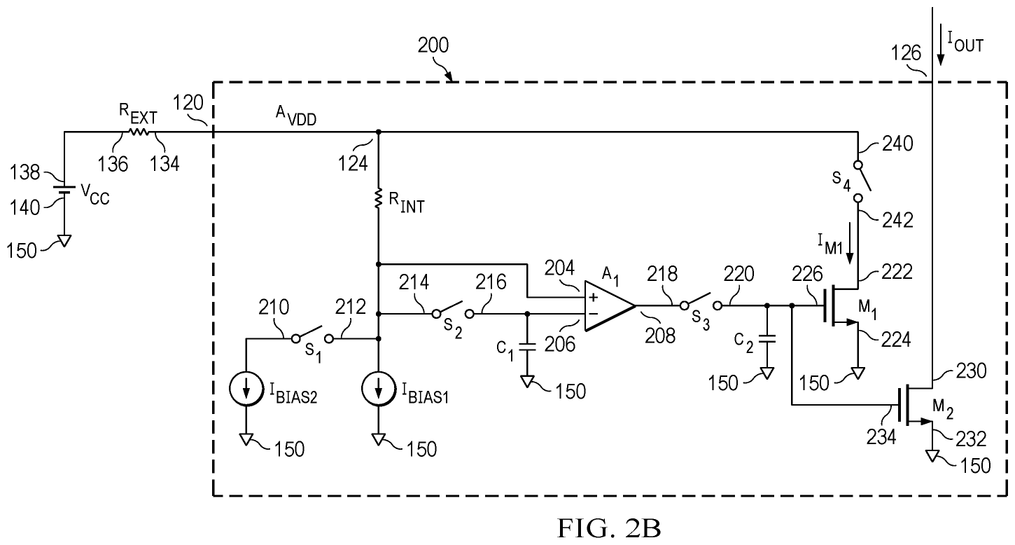

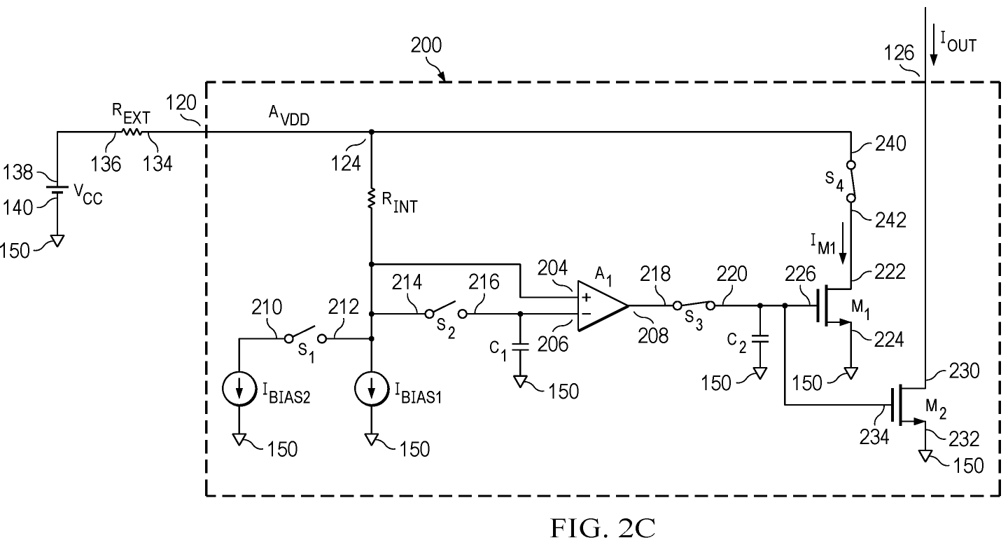

FIG. 2A illustrates detector 200 which is an example implementation of detector 104 of FIG. 1. Detector 200 includes detector input 124 and detector output 126. Detector input 124 is adapted to be coupled to system input 120. Detector output 126 is coupled to system output 122 via input buffer 108 (shown in FIG. 1).

Detector 200 includes operational amplifier A₁ which includes first amplifier input 204 (e.g., non-inverting input), second amplifier input 206 (e.g., inverting input) and amplifier output 208. First amplifier input 204 is coupled to detector input 124 via resistor R_{INT} (e.g., around 500K ohms) (may also be referred to as the “first resistor”). Detector 200 includes first switch S₁ which includes first terminal 210 and includes second terminal 212 coupled to first amplifier input 204. When S₁ is closed (e.g., S₁ is conducting such that terminal 210 is connected to terminal 212), and thus a conduction path is provided for a current through S₁. When S₁ is opened (e.g., S₁ is non-conducting such that terminal 210 is electrically isolated from terminal 212) current does not flow through S₁. Detector 200 includes second switch S₂ which includes first terminal 214 coupled to first amplifier input 204 and includes second terminal 216 coupled to second amplifier input 206. S₁ and S₂ may be implemented using similar (or identical) components. In some example embodiments, S₁ and S₂ are implemented with transistors (e.g., n-channel transistors or NMOS transistors).

Detector 200 includes first bias current source I_{BIAS1} (e.g., around 40 micro-amps) coupled between first amplifier input 204 and common potential 150 (e.g., ground). Detector 200 includes second bias current source I_{BIAS2} (e.g., around 1 micro-amp) coupled between first terminal 210 of first switch S₁ and common potential 150.

Detector 200 includes third switch S₃ which includes first terminal 218 coupled to amplifier output 208 and includes second terminal 220. Detector 200 includes first transistor M₁ (e.g., NMOS transistor) which includes first current terminal 222 (e.g., drain), second current terminal 224 (e.g., source) coupled to common potential 150, and control terminal 226 (e.g., gate) coupled to second terminal 220 of third switch S₃.

Detector 200 includes fourth switch S₄ which includes first terminal 240 coupled to system input 120 (and also coupled to detector input 124) and second terminal 242 coupled to first current terminal 222 of first transistor M₁. In some example embodiments, S₃ and/or S₄ are implemented with transistors (e.g., NMOS transistors).

Detector 200 includes first capacitor C₁ (e.g., around 5 pico-farads) coupled between second amplifier input 206 and common potential 150 and includes second capacitor C₂ (e.g., around 15 pico-farads) coupled between control terminal 226 of first transistor M₁ and common potential 150.

In some example embodiments, detector 200 includes second transistor M₂ (e.g., NMOS transistor) which includes first current terminal 230 (e.g., drain) coupled to detector output 126 which is coupled to system output 122 via input buffer 108 (illustrated in FIG. 1). Second transistor M₂ includes second current terminal 232 (e.g., source) coupled to common potential 150 and includes control terminal 234 (e.g., gate) coupled to second terminal 220 of third switch S₃. Thus, control terminal 234 of M₂ is coupled to control terminal 226 of M₁. In some example embodiments, M₁ and M₂ are identical (or similar) to one another (e.g., M₁ and M₂ have the same characteristics).

A user may couple external reference resistor R_{EXT} between system input 120 and voltage supply V_{CC} in the supply path. As a result, voltage Av DD appears at system input 120.

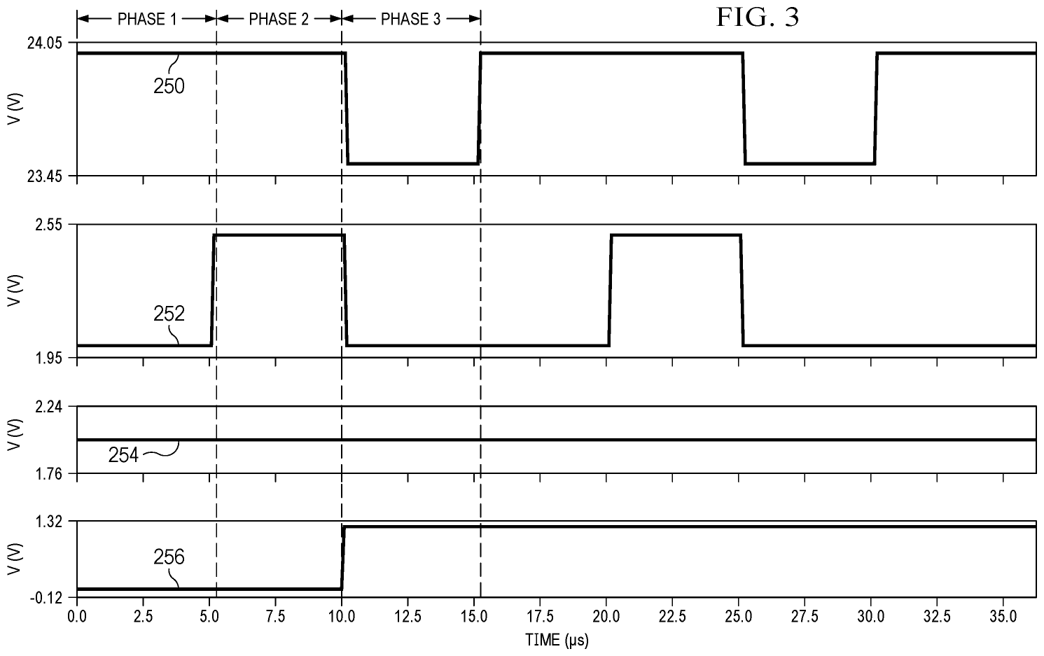

In some example embodiments, detector 200 operates in three phases. The states of switches S₁, S₂, S₃ and S₄ in phases 1, 2 and 3 are shown in FIGS. 2A, 2B and 2C, respectively. FIG. 3 illustrates voltages generated in phases 1, 2 and 3. In FIG. 3, the x-axis represents time (in micro-seconds), and the y-axis represents voltage (in volts). In FIG. 3, graph 250 represents voltage A_{VDD} at system input 120, graph 252 represents a voltage at first amplifier input 204, graph 254 represents a voltage at second amplifier input 206, and graph 256 represents a voltage across control terminal 226 and second terminal 224 of M₁ (e.g., gate-to-source voltage V_{GS} of M₁).

In phase 1, illustrated in FIG. 2A, switches S₁ and S₂ are closed, and switches S₃ and S₄ are opened. Thus, first amplifier input 204 and second amplifier input 206 are connected. Since the voltage across first amplifier input 204 and second amplifier input 206 is zero, the voltage at amplifier output 208 is near zero. In phase 1, current conducts through S₂ and, as a result, capacitor C₁ is charged (e.g., C₁ is charged to around 1.95V).

In phase 1, voltage A_{VDD} (graph 250) is approximately 24V. Because in phase 1 first amplifier input 204 and second amplifier input 206 are shorted together, the voltage at first amplifier input 204 (graph 252) and the voltage at second amplifier input 206 (graph 254) are at the same potential (e.g., around 1.95V). Also, in phase 1, because switch S₃ is opened and capacitor C₂ is not charged, the voltage across control terminal 226 and second current terminal 224 of M₁ (graph 256) is approximately zero.

In phase 2, illustrated in FIG. 2B, switches S₁ and S₂ are opened, and switches S₃ and S₄ continue to remain open. Because second current source I_{BIAS2} is disconnected from R_{INT}, current through R_{INT} falls (e.g., current through R_{INT} falls by around 1 micro-amp), and, as a result, the voltage at first amplifier input 204 rises (e.g., voltage at first amplifier input 204 rises by around 500 mV). Because the voltage at second amplifier input 206 is held constant (as shown by graph 254 in FIG. 3) by capacitor C₁ and the voltage at first amplifier input 204 rises above the voltage at second amplifier input 206 (e.g., the voltage at first amplifier input 204 is around 500 mV higher than voltage at second amplifier input 206), the voltage at amplifier output 208 rises (e.g., the voltage at amplifier output 208 rises to around A*500 mV, where A is the open loop gain of amplifier A₁). Because the resistance of R_{INT} (e.g., around 500K ohms) is much greater than the resistance of R_{EXT} (e.g., between around 700 ohms to around 4K ohms), any change in the voltage across R_{EXT}, due to the removal of I_{BIAS2}, is negligible, and, as such, voltage A_{VDD} remains approximately the same.

Thus, in phase 2, voltage A_{VDD} (graph 250) remains approximately the same (e.g., around 24V); the voltage at first amplifier input (graph 252) rises by around 500 mV; and the voltage at second amplifier input (graph 254) is held constant. Because in phase 2, switch S₃ remains open, capacitor C₂ is not charged. Thus, the voltage across control terminal 226 and second current terminal 224 of M₁ (graph 256) is approximately zero.

In phase 3, illustrated in FIG. 2C, switches S₁ and S₂ remain open but switches S₃ and S₄ are closed. Thus, amplifier output 208 is coupled to control terminal 226 of first transistor M₁, and first current terminal 222 of M₁ is coupled to detector input 124. As such, capacitor C₂ is charged and the voltage across control terminal 226 and second current terminal 224 of M₁ (e.g., the gate-to-source voltage of M₁) rises which causes M₁ to conduct. As current I_{M1} through M₁ rises, current through R_{EXT} also rises which causes voltage A_{VDD} to fall. Transistor M₁ and resistor R_{INT} effectively form a negative feedback path from amplifier output 208 to first amplifier input 204, because as M₁ draws more current voltage A_{VDD} falls further. Since in phase 3, current through R_{INT} remains constant (e.g., I_{BIAS1}), the voltage at first amplifier input 204 falls as voltage A_{VDD} falls. At steady state, the negative feedback path forces the voltage at first amplifier input 204 to fall (e.g., the voltage at first amplifier input 204 falls by 500 mV) to be approximately equal to the voltage at second amplifier input 206. Thus, voltage A_{VDD} falls by an equal amount (e.g., voltage A_{VDD} falls by around 500 mV) which causes the voltage across R_{EXT} to rise by an equal amount (e.g., the voltage across R_{EXT} rises by ΔV which in some example embodiments is around 500 mV). Because the rise in the voltage (e.g., ΔV) across R_{EXT} is caused by current I_{M1} flowing through transistor M₁, the resistance of R_{EXT} may be determined from ΔV and current I_{M1} flowing through M₁. In some example embodiments, ΔV can be determined by:

ΔV=(I_{BIAS2})*(R_{INT}) (1)

where ΔV is the rise in the voltage across R_{EXT}.

Because current I_{M1} through transistor M₁ is correlated to the voltage across control terminal 226 and second current terminal 224 of M₁ (e.g., gate-to-source voltage V_{GS} of M₁), the voltage across control terminal 226 and second current terminal of M₁ may be measured from the voltage across capacitor C₂. Based on the voltage across capacitor C₂, current I_{M1} through M₁ is determined, and the resistance of R_{EXT} is determined from I_{M1} and ΔV.

In some example embodiments, transistors M₁ and M₂ are identical to one another (e.g., M₁ and M₂ have the same characteristics). Because control terminal 226 of M₁ is coupled to control terminal 234 of M₂, and second current terminal 224 of M₁ and second current terminal 232 of M₂ are both coupled to common potential 150, M₁ and M₂ conduct equal amount of current. Thus, current I_{OUT} through M₂ is equal to current I_{M1} through M₁. In response to I_{OUT}, input buffer 108 (shown in FIG. 1) draws I_{IN} from sensor 132 (illustrated in FIG. 1) or provides I_{IN} to sensor 132.

In phase 3, voltage A_{VDD} (graph 250) falls by approximately 500 mV to around 23.5V, the voltage at first amplifier input (graph 252) falls by 500 mV to around 1.95V and the voltage at second amplifier input (graph 254) is held constant. Because in phase 3, switch S₃ is closed, capacitor C₂ is charged. Thus, the voltage across control terminal 226 and second terminal 224 of M₁ (graph 256) rises (e.g., voltage rises to around 1.32V).

In some example embodiments, input buffer 108 may include an A/D converter (not shown in FIG. 1) which converts I_{OUT} to digital codes. The digital codes may be provided to a micro-controller or a processor in input buffer 108 (not shown in FIG. 1) which draws or provides current I_{IN}.

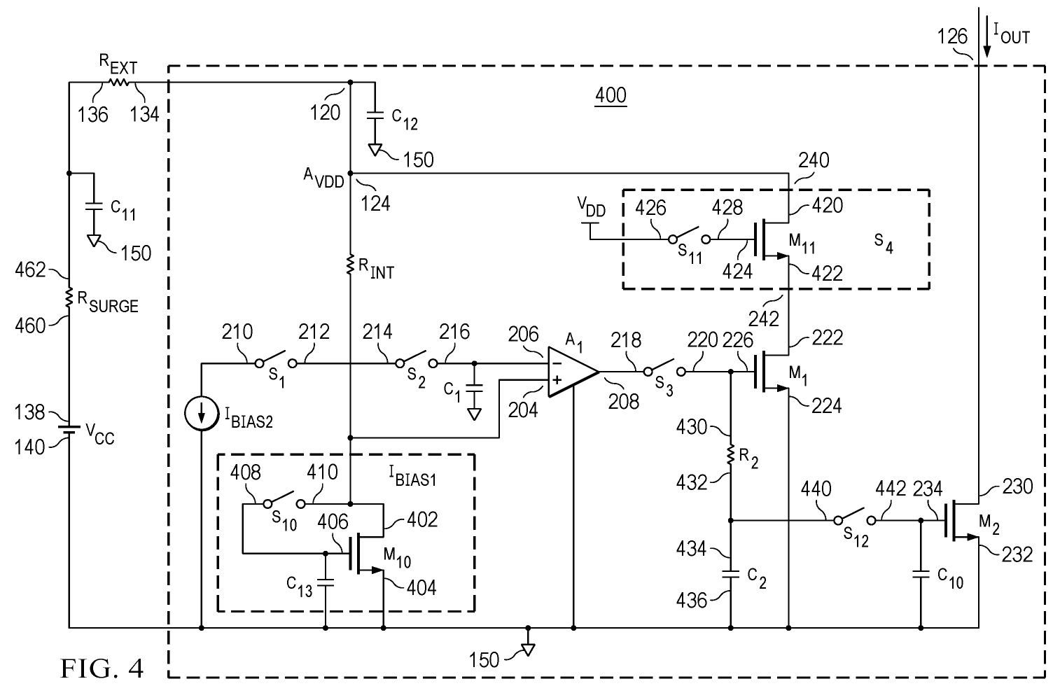

FIG. 4 illustrates detector 400 which is an example implementation of detector 200 of FIGS. 2A-2C. Portions of detector 400 of FIG. 4 are the same as detector 200 of FIGS. 2A-2C. As such, these similar features share the same reference numbers in FIGS. 4 and 2A-2C.

Detector 400 includes first bias current source I_{BIAS1} coupled between first amplifier input 204 and common potential 150. In some example embodiments, I_{BIAS1} is implemented with transistor M₁₀ (e.g., NMOS transistor), switch S₁₀ and capacitor C₁₃. Transistor M₁₀ includes first current terminal 402 (e.g., drain) coupled to first amplifier input 204, second current terminal 404 (e.g., source) coupled to common potential 150 and includes control terminal 406 (e.g., gate). Switch S₁₀ includes first terminal 408 coupled to control terminal 406 of M₁₀ and includes second terminal 410 coupled to first current terminal 402 of M₁₀. Capacitor C₁₃ is coupled between control terminal 406 of M₁ and common potential 150. When switch S₁₀ is closed, first current terminal 402 and control terminal 406 of M₁ are coupled together, and, as such, M₁₀ has a diode connection and capacitor C₁₃ is charged. When switch S₁₀ is opened, capacitor C₁₃ maintains a constant voltage across control terminal 406 and second current terminal 404 of M₁₀, and, as such, a constant current (e.g., I_{BIAS1}) flows through M₁₀. In some example embodiments, capacitor C₁₃ is charged to a voltage level necessary to operate M₁₀ in a saturation region so that a constant current (e.g., I_{BIAS1}) flows through M₁₀. In some example embodiments, switch S₁₀ is periodically opened and closed to recharge capacitor C₁₃, thus replenishing any charge which may be lost in capacitor C₁₃ due to leakage. In some example embodiments, current source I_{BIAS2} may be implemented in similar or substantially similar manner as current source I_{BIAS1}.

Detector 400 includes switch S₄ which is implemented with transistor M₁₁ (e.g., NMOS transistor) and switch S₁₁. Transistor M₁₁ includes first current terminal 420 (e.g., drain) coupled to detector input 124, second current terminal 422 (e.g., source) coupled to first current terminal 222 of transistor M₁ and includes control terminal (e.g., gate). Switch S₁₁ includes first terminal 426 coupled to voltage supply V_{DD} and includes second terminal 428 coupled to control terminal 424 of M₁₁. When switch S₁₁ is closed, control terminal 424 of M₁₁ is coupled to voltage supply V_{DD}, and, as such, M₁₁ conducts. Thus, first current terminal 222 of M₁ is coupled to detector input 124 via M₁₁. When switch S₁₁ is opened, V_{DD} is disconnected from control terminal 424 of M₁₁, and, as such, M₁₁ does not conduct, and first current terminal 222 of M₁ is disconnected from detector input 124.

In some example embodiments, resistor R₂ (e.g., around 50K ohms) is coupled between control terminal 226 of M₁ and capacitor C₂. Resistor R₂ includes first terminal 430 coupled to control terminal 226 of M₁ and includes second terminal 432. Capacitor C₂ includes first terminal 434 coupled to second terminal 432 of resistor R₂ and includes second terminal 436 coupled to common potential 150.

In some example embodiments, detector 400 includes capacitor C₁₀ coupled between control terminal 234 of M₂ and common potential 150. Detector 400 includes switch S₁₂ which includes first terminal 440 coupled to first terminal 434 of capacitor C₂ and includes second terminal 442 coupled to control terminal 234 of M₂. When switch S₁₂ is closed, control terminal 234 of M₂ is coupled to control terminal 226 of M₁ and capacitor C₁₀ is charged. As such, transistor M₂ conducts and draws current I_{OUT}. The voltage across control terminal 226 and second current terminal 224 of M₁ (e.g., gate-to-source voltage V_{GS} of M₁) is approximately at the same level as the voltage across control terminal 234 and second current terminal 232 of M₂. Thus, M₁ and M₂ conduct the same amount of current (e.g., I_{OUT} is equal to I_{M1}). When switch S₁₂ is opened, the voltage across control terminal 234 and second current terminal 232 of M₂ is held at a constant voltage by capacitor C₁₀, thus allowing transistor M₂ to continue to conduct. In some example embodiments, switch S₁₂ is periodically opened and closed to recharge capacitor C₁₀, thereby replenishing any charge which may be lost in capacitor C₁₀ due to leakage.

To protect detector 400 from an instantaneous surge in voltage supply V_{CC}, surge resistor R_{SURGE} (e.g., around 1K ohms) is coupled in series in the supply path. Resistor R_{SURGE} includes first terminal 460 coupled to first terminal 138 of V_{CC} and includes second terminal 462 coupled to second terminal 136 of resistor R_{EXT}. Resistor R_{SURGE} limits current flowing in the supply path. Capacitor C₁₁ (e.g., around 1 micro-farad) is coupled between second terminal 462 of R_{SURGE} and common potential 150. At high frequencies, capacitor C₁₁ acts as a short circuit (e.g., capacitor C₁₁ has a very low impedance at high frequencies), thereby providing a path for any instantaneous surge current to flow to ground. At low frequencies, capacitor C₁₁ acts as an open circuit (e.g., capacitor C₁₁ has a very high impedance at low frequencies), thereby coupling V_{CC} to system input 120.

In some example embodiments, capacitor C₁₂ (e.g., around 1 micro farad) is coupled between system input 120 and common potential 150. Capacitor C₁₂ maintains a stable DC voltage (e.g., AVDD) at system input 120 by reducing AC ripple.

Because detectors 100, 200 and 400 are configured to sense and determine the resistance of an external resistor (e.g., R_{EXT}) coupled in the supply path without requiring an additional pin in an IC, the number of pins in an IC package is reduced. As a result, the size of an IC package is reduced, thereby reducing fabrication cost of an IC package.

The circuits described herein may include one or more semiconductor elements (such as transistors), one or more passive elements (such as resistors, capacitors and/or inductors), and/or one or more sources (such as voltage and/or current sources). The circuits may include only semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end-user and/or a third party. While some example embodiments may include certain elements implemented in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, the term “couple” may cover connections, communications, or signal paths that enable a functional relationship consistent with this description. For example, if device A provides a signal to control device B to perform an action, then: (a) in a first example, device A is coupled to device B; or (b) in a second example, device A is coupled to device B through intervening component C if intervening component C does not substantially alter the functional relationship between device A and device B, such that device B is controlled by device A via the control signal provided by device A. Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, in this description, a circuit or device that includes certain components may instead be adapted to be coupled to those components to form the described circuitry or device. For example, a structure described as including one or more semiconductor elements (such as transistors), one or more passive elements (such as resistors, capacitors and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end-user and/or a third party.

As used herein, the terms “terminal”, “node”, “interconnection”, “ball” and “pin” are used interchangeably. Unless specifically stated to the contrary, these terms are generally used to mean an interconnection between or a terminus of a device element, a circuit element, an integrated circuit, a device or other electronics or semiconductor component.

While some example embodiments suggest that certain elements are included in an integrated circuit while other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

While the use of particular transistors are described herein, other transistors (or equivalent devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

While certain components may be described herein as being of a particular process technology, these components may be exchanged for components of other process technologies. Circuits described herein are reconfigurable to include the replaced components to provide functionality at least partially similar to functionality available before the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in series or in parallel between the same two nodes as the single resistor or capacitor. Also, uses of the phrase “ground” or “ground terminal” in this description include a chassis ground, an Earth ground, a floating ground, a virtual ground, a digital ground, a common ground, and/or any other form of ground connection applicable to, or suitable for, the teachings of this description. Unless otherwise stated, “about”, “approximately”, or “substantially” preceding a value means +/−10 percent of the stated value, or, if the value is zero, a reasonable range of values around zero.

What is claimed is:

1. A system comprising:
a system input;
a system output;
an operational amplifier comprising:
a first amplifier input coupled to the system input;
a second amplifier input; and
an amplifier output;
a first switch including a first terminal and including a second terminal coupled to the first amplifier input;
a second switch including a first terminal coupled to the first amplifier input and a second terminal coupled to the second amplifier input;
a first bias current source coupled between the first amplifier input and a common potential;
a second bias current source coupled between the first terminal of the first switch and the common potential;
a third switch including a first terminal coupled to the amplifier output and including a second terminal;
a first transistor including a first current terminal, a second current terminal coupled to the common potential, and a control terminal coupled to the second terminal of the third switch; and
a fourth switch including a first terminal coupled to the system input and a second terminal coupled to the first current terminal of the first transistor.

2. The system of claim 1, further comprising a first capacitor coupled between the second amplifier input and the common potential.

3. The system of claim 1, further comprising a second capacitor coupled between the control terminal of the first transistor and the common potential.

4. The system of claim 1, further comprising a second transistor including a first current terminal coupled to the system output, a second current terminal coupled to the common potential, and a control terminal coupled to the second terminal of the third switch.

5. The system of claim 1, further comprising a first resistor coupled between the system input and the first amplifier input.

6. An external resistor detection circuit, comprising:
an operational amplifier including a first amplifier input adapted to be coupled to the external resistor and including a second amplifier input and an amplifier output;
a first switch including a first terminal and including a second terminal coupled to the first amplifier input;
a second switch including a first terminal coupled to the first amplifier input and a second terminal coupled to the second amplifier input;
a first bias current source coupled between the first amplifier input and a common potential;
a second bias current source coupled between the first terminal of the first switch and the common potential;
a third switch including a first terminal coupled to the amplifier output and including a second terminal;
a first transistor including a first current terminal, a second current terminal coupled to the common potential, and a control terminal coupled to the second terminal of the third switch;
a fourth switch including a first terminal coupled to the system input and a second terminal coupled to the first current terminal of the first transistor;
a first capacitor coupled between the second amplifier input and the common potential; and
a second capacitor coupled between the control terminal of the first transistor and the common potential.

7. The system of claim 6, further comprising a second transistor including a first current terminal coupled to a system output, a second current terminal coupled to the common potential, and a control terminal coupled to the second terminal of the third switch.

8. The system of claim 6, further comprising a first resistor coupled between the external resistor and the first amplifier input.

9. A circuit having an external terminal adapted to be coupled to an external resistor, the circuit comprising:
an operational amplifier including a first amplifier input coupled to the external terminal and including a second amplifier input and an amplifier output;
a first capacitor coupled between the second amplifier input and a common potential; and
a feedback path including a first terminal coupled to the amplifier output and a second terminal coupled to the external terminal, the feedback path configured to provide an output current corresponding to the resistance of the external resistor.

10. The circuit of claim 9, further comprising:
a first switch including a first terminal and including a second terminal coupled to the first amplifier input;
a second switch including a first terminal coupled to the first amplifier input and a second terminal coupled to the second amplifier input;
a first bias current source coupled between the first amplifier input and the common potential; and
a second bias current source coupled between the first terminal of the first switch and the common potential.

11. The circuit of claim 9, wherein the feedback path comprises:
a third switch including a first terminal coupled to the amplifier output and including a second terminal;
a first transistor including a first current terminal, a second current terminal coupled to the common potential, and a control terminal coupled to the second terminal of the third switch; and
a fourth switch including a first terminal coupled to the external terminal and a second terminal coupled to the first current terminal of the first transistor.

12. The circuit of claim 11, further comprising a second capacitor coupled between the control terminal of the first transistor and the common potential.

13. The circuit of claim 11, further comprising a second transistor including a first current terminal coupled to a circuit output, a second current terminal coupled to the common potential, and a control terminal coupled to the second terminal of the third switch.

14. The circuit of claim 9, further comprising a first resistor coupled between the external terminal and the first amplifier input.

15. A system comprising:
a system input;
a system output;
an operational amplifier comprising:
a first amplifier input coupled to the system input;
a second amplifier input; and
an amplifier output;
a first switch including a first terminal and including a second terminal coupled to the first amplifier input;
a second switch including a first terminal coupled to the first amplifier input and a second terminal coupled to the second amplifier input;
a first bias current source coupled between the first amplifier input and a common potential;
a second bias current source coupled between the first terminal of the first switch and the common potential; and
a feedback path including a first terminal coupled to the amplifier output and a second terminal coupled to the system input.

16. The system of claim 15, wherein the feedback path comprises:
a third switch including a first terminal coupled to the amplifier output and including a second terminal;
a first transistor including a first current terminal, a second current terminal coupled to the common potential, and a control terminal coupled to the second terminal of the third switch; and
a fourth switch including a first terminal coupled to the system input and a second terminal coupled to the first current terminal of the first transistor.

17. The system of claim 15, further comprising a first capacitor coupled between the second amplifier input and the common potential.

18. The system of claim 15, further comprising a second capacitor coupled between the control terminal of the first transistor and the common potential.
